(19) United States
(12) Patent Application Publication
(10) Pub. No.: US 2026/0366883 A1
(43) Pub. Date: Nov. 19, 2026

(54) USER SUPPORT SYSTEM AND USER SUPPORT METHOD

(71) Applicant: TOYOTA JIDOSHA KABUSHIKI KAISHA, Aichi-ken (JP)

(72) Inventors: Masato SAKOU, Takarazuka-shi (JP); Kei KAWASAKI, Funabashi-shi (JP); Yuta EZOE, Tokyo-to (JP); Yuki ICHIOKA, Kawasaki-shi (JP); Nasif NAYEER, Tokyo-to (JP)

(21) Appl. No.: 19/665,016

(22) Filed: May 1, 2026

(30) Foreign Application Priority Data
May 13, 2025 (JP) 2025-080662

(51) Int. Cl. G01C 21/34; B60L 58/12; G06F 30/15

(52) U.S. Cl. CPC G01C 21/3469; B60L 58/12; G01C 21/3492; G06F 30/15; B60L 2240/62; B60L 2240/68

(57) ABSTRACT

The user support system supports users in selecting a small electric mobility vehicle capable of reaching their destination in a small electric mobility vehicle renting service. The processing circuitry of the user support system receives a candidate for a small electric mobility vehicle selected by a user, as well as the user's current location and destination. The processing circuitry obtains battery information including the charge amount, deterioration state, and power consumption of the selected candidate's battery, and obtains predicted pedestrian flow in a finite area that includes the route from the current location to the destination. Then, the processing circuitry generates a digital twin space of the finite area reflecting the predicted pedestrian flow, performs a simulation in the digital twin space to determine whether the selected candidate can reach the destination based on the current location, destination, and battery information, and presents the simulation results to the user.

### CROSS-REFERENCE TO RELATED APPLICATION

The present application claims priority under 35 U.S.C. § 119 to Japanese Patent Application No. 2025-080662, filed on May 13, 2025, the contents of which application are incorporated herein by reference in their entirety.

### BACKGROUND

### Field

The present disclosure relates to a system and method for supporting users in selecting small electric mobility vehicles, which is particularly suitable for use in a service where users rent small electric mobility vehicles.

### Background Art

JP2022-064519A discloses a conventional technology related to a charging system for a mobility vehicle that travels on electricity, such as an electric vehicle. However, as documents illustrating the technical level in the technical field related to this disclosure, in addition to JP2022-064519A, JP2014-202641A can also be cited as an example.

According to the prior art disclosed in JP2022-064519A, each of multiple users obtains the remaining capacity of a rechargeable battery equipped in a mobility vehicle that is planned to be used. Then, for each mobility vehicle, a required amount of battery power is estimated based on the planned use location and the destination. In this estimation, the number of passengers boarding the mobility vehicle other than the user, the planned time information for the user to use the mobility vehicle, and the traffic congestion situation on the route from the planned use location to the destination are taken into account. Furthermore, for each mobility vehicle, it is determined whether the remaining battery capacity is equal to or greater than the required power amount. Then, a mobility vehicle with a remaining battery capacity equal to or greater than the required power amount is arranged to be sent to the user's planned use location.

However, the visible remaining battery capacity is not the only factor that affects the travel range of an electric mobility vehicle. Even if the visible remaining battery capacity appears to be the same, the travel range may differ depending on the degree of battery degradation. Furthermore, while considering traffic congestion on the route may be sufficient for an electric vehicle, in the case of a small electric mobility vehicle that is permitted to travel in the same areas as pedestrians, such as sidewalks, the crowdedness of passages due to pedestrians and their movements affect the traveling state of the small electric mobility vehicle, thus changing the remaining battery capacity. Therefore, depending on the small electric mobility vehicle selected by the user, there is a risk that the destination may not be reached.

### SUMMARY

The present disclosure has been made in view of the above-mentioned problem. One objective of the present disclosure is to provide a user support system and method that can help users select small electric mobility vehicles capable of reaching their destination in a rental service for small electric mobility vehicles.

According to one embodiment of the present disclosure, a user support system comprises processing circuitry. The processing circuitry is configured to receive a candidate for a small electric mobility vehicle selected by a user, and receive the user's current location and destination. Also, the processing circuitry is configured to obtain battery information including the charge amount, degradation state, and power consumption of the selected candidate's battery, and obtain predicted pedestrian flow in a finite area that includes the route from the current location to the destination. Furthermore, the processing circuitry is configured to generate a digital twin space of the finite area reflecting the predicted pedestrian flow, perform a simulation in the digital twin space to determine whether the selected candidate can reach the destination based on the current location, destination, and battery information, and present the simulation results to the user.

According to one embodiment of the present disclosure, a user support method comprises at least the following seven steps. The first step is a step of receiving a candidate for a small electric mobility vehicle selected by a user. The second step is a step of receiving the user's current location and destination. The third step is a step of obtaining battery information including the charge amount, deterioration state, and power consumption of the candidate battery. The fourth step is a step of obtaining predicted pedestrian flow in a finite area including the route from the current location to the destination. The fifth step is a step of generating a digital twin space of the finite area reflecting the predicted pedestrian flow. The sixth step is a step of performing a simulation in the digital twin space to determine whether the selected candidate can reach the destination based on the current location, destination, and battery information. The seventh step is a step of presenting the simulation results to the user.

According to one embodiment of the present disclosure, it is possible to present to a user whether a candidate small electric vehicle selected by the user can reach the destination or not, considering not only the battery charge amount at the time of departure but also the battery degradation state, and further considering the pedestrian flow in the route from the current location to the destination. This enables support in helping users select a small electric mobility vehicle capable of reaching the destination.

### BRIEF DESCRIPTION OF DRAWINGS

FIG. 1 is a diagram explaining an overview of a service to which a user support system according to one embodiment of the disclosure is applied.

FIG. 2 is a functional block diagram for explaining the functions of the user support system.

FIG. 3 is a diagram showing an example of presenting simulation results to a user.

FIG. 4 is a flowchart showing a process of determining notification content to a user.

### DETAILED DESCRIPTION

### 1. Overview of the Service to Which the User Support System is Applied

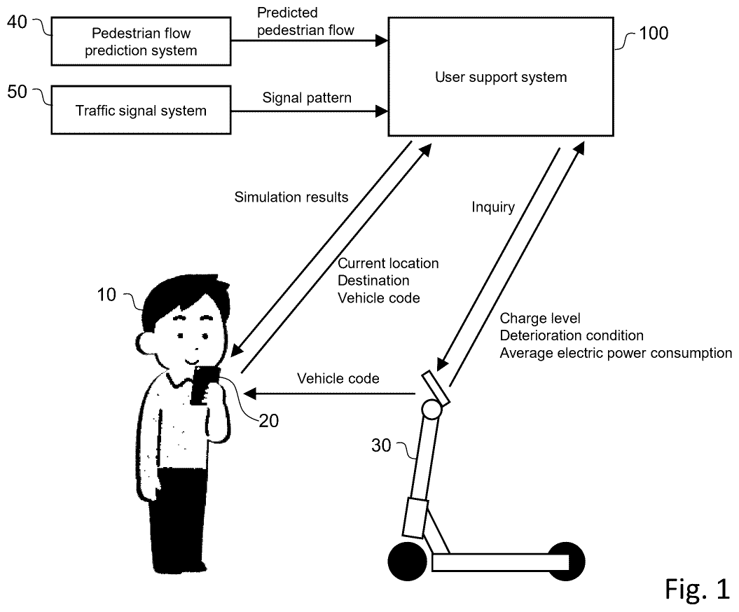

In one embodiment of the present disclosure, the user support system is applied to a service where users rent small electric mobility vehicles. The following description provides an overview of this rental service using FIG. 1. Hereinafter, in the following description, a small electric mobility vehicle, that is, a Micro-Mobility Vehicle, will be simply referred to as a micro-mobility.

The rental service according to the present embodiment is a service in which a user 10 rents a micro-mobility 30 for the purpose of transportation. The micro-mobility 30 is a small vehicle that runs on power supplied from a rechargeable battery, and includes, for example, electric kick scooters, electric bicycles, and small electric cars. However, while automobiles are vehicles that travel on roads isolated from pedestrians, the micro-mobility 30 rented in the rental service according to the present embodiment is a vehicle that is permitted to travel in the same space as pedestrians.

The micro-mobilities 30 available for rental are placed at ports installed throughout the city. When there are multiple micro-mobilities 30 at a port, the user 10 can choose a preferred one from among the micro-mobilities 30 placed at the port. The ports may or may not have an administrator present. Regardless of the presence or absence of an administrator, the user 10 can freely rent a micro-mobility 30.

The user 10 uses a user terminal 20, such as a smartphone, to rent the micro-mobility 30. The micro-mobility 30 is equipped with a reading code (QR code or barcode). The user 10 decides on a candidate micro-mobility 30 that they want to rent, namely, the micro-mobility 30 they wish to use to reach their destination, and scans the reading code using the user terminal 20. When the user 10 scans the reading code with the user terminal 20, the user terminal 20 is connected to a user support system 100, which is a cloud-based server system. Then, the vehicle code of the micro-mobility 30 embedded in the reading code is notified to the user support system 100 via the user terminal 20.

The user support system 100, upon being notified of the vehicle code, performs an information inquiry via mobile communication to the micro-mobility 30 identified by the vehicle code. In response to the information inquiry, the micro-mobility 30 transmits the battery charge amount, the battery degradation condition, and the average power consumption to the user support system 100. The micro-mobility 30 is equipped with a battery management system (BMS) for managing the battery. The battery charge amount, the battery degradation status, and the average power consumption are periodically calculated by the BMS and stored in memory.

When renting the micro-mobility 30, the user 10 inputs a destination into the user terminal 20. When the user 10 inputs the destination into the user terminal 20, the input destination is transmitted from the user terminal 20 to the user support system 100 along with the current location measured by the GPS built into the user terminal 20.

The user support system 100 obtains a predicted pedestrian flow from the pedestrian flow prediction system 40. The pedestrian flow prediction system 40 is a cloud-based server system. The pedestrian flow predicted by the pedestrian flow prediction system 40 is the pedestrian flow in a finite area including the route from the current location of the user 10 to the destination. The pedestrian flow prediction system 40 has a pedestrian flow model learned from past pedestrian flow data. The pedestrian flow prediction system 40 obtains data on current pedestrian flow from surveillance cameras installed throughout the city and location information from smartphones carried by pedestrians, and calculates predicted future pedestrian flow by inputting them into a pedestrian flow model. The predicted pedestrian flow calculated by the pedestrian flow prediction system 40 is the predicted pedestrian flow for the time period from the current time until the time when the user 10 reaches the destination. As for the predicted pedestrian flow, for example, the population density at the timing when the user 10 passes may be used, or the speed at which a crowd of pedestrians moves, or the directionality of the movement of the crowd of pedestrians (tendency to move in a specific direction) may be used, or a combination of these may be used. In an example where the directionality of the movement of the crowd of pedestrians is used for pedestrian flow prediction, when the moving direction of the crowd of pedestrians differs from the moving direction of the micro-mobility 30, it may be calculated as taking more time to move, that is, consuming more power.

The user support system 100 obtains future signal patterns from a traffic signal system 50. The traffic signal system 50 is a system that integrally controls the signal patterns of traffic lights installed throughout the city. The traffic signal system 50 determines the signal patterns according to predetermined rules, so future signal patterns can be calculated by following these rules. The future signal pattern obtained from the traffic signal system 50 is a signal pattern for the time period from the current time until the user 10 reaches the destination.

The user support system 100 performs a simulation, based on various obtained data, to determine whether the micro-mobility 30 selected by the user 10 can reach the destination without running out of battery. The user support system 100 sends the simulation results to the user terminal 20 and displays them on the display of the user terminal 20. Based on the presented simulation results, the user 10 can decide whether to use the selected micro-mobility 30 as is or to choose a different micro-mobility 30.

### 2. Functions of the User Support System

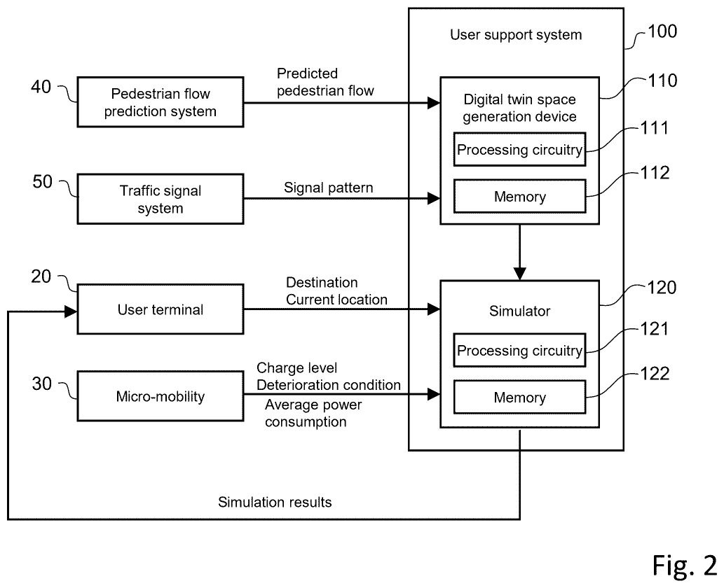

Next, the functions of the user support system 100 will be explained. FIG. 2 is a functional block diagram for explaining the functions of the user support system 100. As shown in FIG. 2, the user support system 100 comprises a digital twin space generation device 110 and a simulator 120. The digital twin space generation device 110 is realized through the cooperation of hardware, comprising processing circuitry 111 and memory 112, and a program stored in the memory 112 that, when executed by the processing circuitry 111, causes the processing circuitry 111 to function as the digital twin space generation device 110. The simulator 120 is realized through the cooperation of hardware, which includes processing circuitry 121 and memory 122, and a program stored in the memory 122 that, when executed by the processing circuitry 121, causes the processing circuitry 121 to function as the simulator 120. However, the hardware may be separate or common between the digital twin space generation device 110 and the simulator 120.

The digital twin space generation device 110 is a device that generates a digital twin space of a finite area including the route from the current location of the user 10 to the destination. The map information for generating a digital twin space is pre-registered in a database constructed in the memory 112 of the digital twin space generation device 110. The map information is always kept up to date. The digital twin space generation device 110 reflects the predicted pedestrian flow obtained from the pedestrian flow prediction system 40 and the signal pattern obtained from the traffic signal system 50 in the digital twin space. As a result, the temporal changes in the predicted pedestrian flow and signal patterns in the future are visualized in the digital twin space. It should be noted that the impact of signal patterns on the power consumption of the micro-mobility 30 is smaller compared to the impact of pedestrian flow on the power consumption of the micro-mobility 30. Therefore, the reflection of signal patterns in the digital twin space may be omitted.

The simulator 120 is a device that performs simulations in the digital twin space generated by the digital twin space generation device 110. The simulator 120 uses information regarding the current location of the user 10 and the destination obtained from the user terminal 20, and the battery information (battery charge amount, battery degradation state, and average power consumption) obtained from the micro-mobility 30 for simulation. In the simulation, it is determined based on the battery information whether the micro-mobility 30 selected by user 10 can reach the destination without running out of battery for all routes from the current location to the destination.

The simulator 120 sends, as a simulation result, information regarding whether the selected micro-mobility 30 can reach the destination to the user terminal 20. When reaching the destination is possible, the simulator 120 further sends information regarding a recommended route from the current location to the destination as a simulation result to the user terminal 20. On the other hand, when reaching the destination is impossible with the selected micro-mobility 30, the simulator 120 searches for charging facilities located between the current location and the destination in the digital twin space. When a charging facility to stop by on the way is found, the simulator 120 sends information about the charging facility to the user terminal 20 as a simulation result.

Moreover, the user support system 100 may allow the user 10 to select from multiple micro-mobilities 30. For example, when the user 10 scans the reading codes of multiple micro-mobilities 30 placed at a port using the user terminal 20, the user support system 100 may determine whether there are any micro-mobilities 30 capable of reaching the destination based on simulations using the battery information of each micro-mobility 30. Then, if there are multiple micro-mobilities 30 capable of reaching the destination, the user support system 100 may recommend to the user 10 the micro-mobility 30 that will have the highest remaining battery capacity upon reaching the destination. On the other hand, when there is no micro-mobility 30 capable of reaching the destination, the user support system 100 may recommend to the user 10 the micro-mobility 30 that can travel the longest distance.

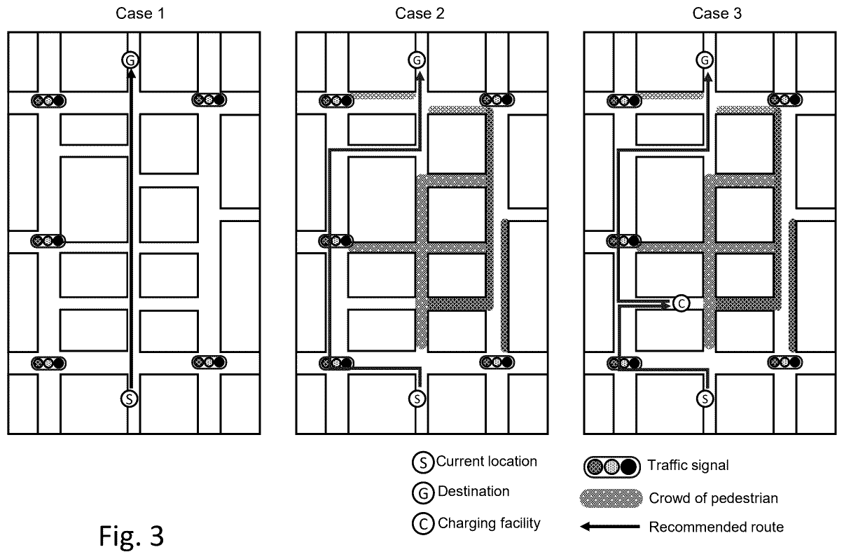

FIG. 3 is an example of a simulation result display shown on the display of the user terminal 20. Case 1 and Case 2 are examples of displaying recommended routes when the micro-mobility 30 can reach the destination from the current location without running out of battery. Case 1 is a scenario where no crowds are occurring anywhere. In this case, the shortest route is displayed as the recommended route. Case 2 is a case where a crowd has formed between the current location and the destination. In this case, the recommended route displayed is the shortest route among those that can avoid the crowd.

Case 3 is an example of displaying a recommended route when the micro-mobility 30 cannot reach the destination from the current location without running out of battery. In this case, charging facilities installed between the current location and the destination are displayed. Then, a route via these charging facilities is displayed as the recommended route.

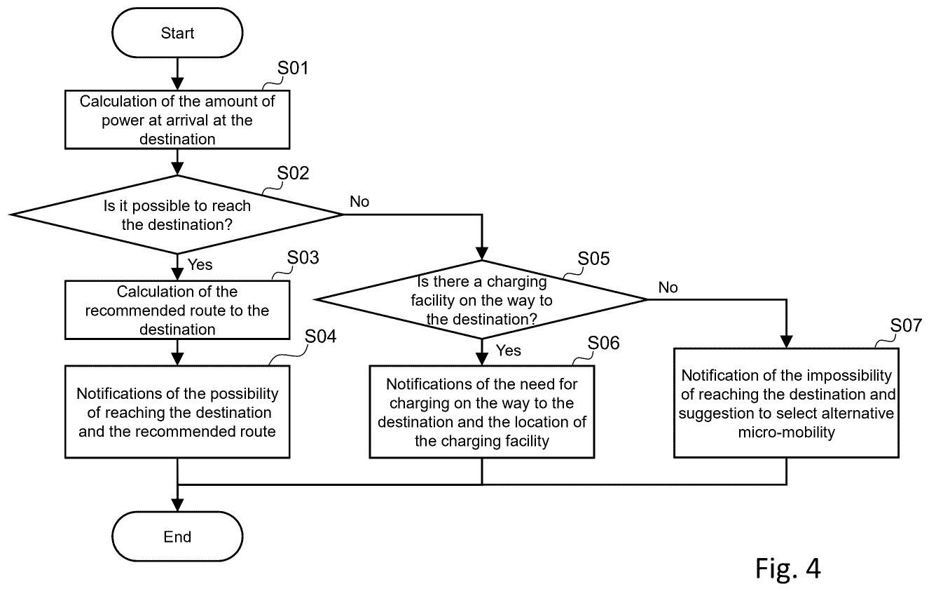

FIG. 4 is a flowchart showing the flow of determining the notification content for the user 10 by the user support system 100. The user support system 100 performs a simulation according to this flowchart to determine the notification content for the user 10.

First, in step S01, the user support system 100 calculates the power amount remaining in the battery when the micro-mobility 30 selected by the user 10 arrives at the destination, through simulation in the digital twin space. In this calculation, the power amount can also take negative values.

Next, in step S02, the user support system 100 determines whether or not the micro-mobility 30 can reach the destination based on the power consumption calculated in step S01. If the power consumption is greater than zero, it is possible to reach the destination, however, if the power consumption is zero or less, it is impossible to reach the destination.

If it is determined in step S02 that it is possible to reach the destination, the user support system 100 executes step S03 and step S04. In step S03, the simulator 120 calculates a recommended route to the destination. The recommended route is, for example, a route that can minimize power consumption. For the calculation of power consumption, parameters such as power consumption per travel distance, speed coefficient (as speed increases, consumption per travel distance increases), and power consumption per stop time may be used. When the micro-mobility 30 is stopped, power-consuming systems such as lights, fans, and audio equipment mounted on the micro-mobility 30 are likely to remain on. Therefore, the power consumption per unit of stop time has a particularly significant impact on the total power consumption to the destination. The power consumption per stop time may be estimated based on a demand forecast of the power consumption system, which takes into account factors such as weather conditions (it is anticipated that fans and other devices may be turned on when it is hot), time of day (it is expected that lights may be brightened when it gets dark), and pedestrian flow conditions (it is anticipated that the likelihood of using fans and other devices increases as it becomes more crowded and the user feels hotter).

Then, in step S04, the user support system 100 notifies the user 10 that it is possible to reach the destination using the selected micro-mobility 30, and also notifies the recommended route calculated in step S03. Furthermore, when the user 10 can select multiple micro-mobilities 30, and some of them are capable of reaching the destination, the user support system 100 recommends to the user 10 the micro-mobility 30 that will have the highest remaining battery capacity upon reaching the destination.

If it is determined in step S02 that it is impossible to reach the destination, the user support system 100 executes step S05. In step S05, the user support system 100 determines whether there is a charging facility on the way to the destination. The charging facility searched for in the digital twin space is a charging facility that can be reached before the power amount of the micro-mobility 30 becomes zero.

In step S05, when it is determined that there is a charging facility on the way to the destination, the user support system 100 executes step S06. In step S06, the user support system 100 notifies the user 10 that charging is necessary on the way to the destination and also notifies the user 10 of the location of the charging facility. It should be noted that the user 10 can select multiple micro-mobilities 30, and none of them are capable of reaching the destination, the user support system 100 recommends to the user 10 the micro-mobility 30 that can travel the longest distance.

In step S05, if it is determined that there is no charging facility on the way to the destination, the user support system 100 executes step S07. In step S07, the user support system 100 notifies the user 10 that it is impossible to reach the destination and proposes selecting an alternative micro-mobility. In one embodiment, if there are other available micro-mobility options at the user's current location, the user support system 100 recommends trying those options. When it is known that there are no other available micro-mobility options at the user's current location but there are available micro-mobility options at a different location, the user support system 100 informs the user 10 of that location. Additionally, the user support system 100 may propose alternative means of transportation other than micro-mobility to the user 10.

### 3. Effects

According to the user support system 100 of the present embodiment, it is possible to present to the user 10 whether the micro-mobility 30 selected by the user 10 can reach the destination or not, considering not only the battery charge amount at the time of departure but also the degradation state of the battery, and further considering the pedestrian flow and signal patterns in the route from the current location to the destination. Thereby, it is possible to support the user 10 in selecting a micro-mobility 30 that can reach the destination.

What is claimed is:

1. A user support system for supporting selection of a small electric mobility vehicle by a user, the system comprising processing circuitry configured to execute:
receiving a candidate for a small electric mobility vehicle selected by the user;
receiving a current location of the user and a destination;
obtaining battery information including a charge amount, a deterioration state, and power consumption of a battery of the candidate;
obtaining predicted pedestrian flow in a finite area including a route from the current location to the destination;
generating a digital twin space of the finite area reflecting the predicted pedestrian flow;
performing a simulation in the digital twin space to determine whether the candidate can reach the destination based on the current location, destination, and battery information; and
presenting a result of the simulation to the user.

2. The user support system according to claim 1, wherein the processing circuitry is configured to further execute:
presenting to the user, in a case where the candidate can reach the destination in the simulation, a recommended route from the current location to the destination for the candidate to reach the destination.

3. The user support system according to claim 2, wherein the processing circuitry is configured to further execute:
recommending to the user, in a case where a plurality of candidates of the small electric mobility vehicle are selected by the user, a candidate among the plurality of candidates having a largest remaining battery capacity when reaching the destination.

4. The user support system according to claim 1, wherein the processing circuitry is f configured to further execute:
presenting to the user, in a case where the candidate cannot reach the destination in the simulation, a charging facility for the candidate to stop by on a way to the destination.

5. The user support system according to claim 4, wherein the processing circuitry is configured to further execute:
recommending to the user, in a case where a plurality of candidates of the small electric mobility vehicle are selected by the user, a candidate among the plurality of candidates capable of traveling a longest distance.

6. The user support system according to claim 1, wherein the processing circuitry is configured to further execute:
obtaining a signal pattern of traffic lights in the finite area; and
reflecting the signal pattern in the digital twin space.

7. The user support system according to claim 1, wherein the processing circuitry is configured to:
further execute predicting a demand for a power consumption system mounted on the small electric mobility vehicle based on the predicted pedestrian flow; and
perform the simulation based on the current location, destination, battery information, and additionally a demand for the power consumption system.

8. A user support method for supporting selection of a small electric mobility vehicle by a user, the method comprising:
receiving a candidate for a small electric mobility vehicle selected by the user;
receiving a current location of the user and a destination;
obtaining battery information including a charge amount, a deterioration state, and power consumption of a battery of the candidate;
obtaining predicted pedestrian flow in a finite area including a route from the current location to the destination;
generating a digital twin space of the finite area reflecting the predicted pedestrian flow;
performing a simulation in the digital twin space to determine whether the candidate can reach the destination based on the current location, destination, and battery information; and
presenting a result of the simulation to the user.
